(19) United States
(12) Patent Application Publication
(10) Pub. No.: US 2017/0098796 A1
(43) Pub. Date: Apr. 6, 2017

(54) WINDOW SUBSTRATE AND DISPLAY APPARATUS INCLUDING SAME

(71) Applicant: SAMSUNG DISPLAY CO., LTD., Yongin-si (KR)

(72) Inventor: Dong-su Yee, Cheonan-si (KR)

(21) Appl. No.: 15/152,474

(22) Filed: May 11, 2016

(30) Foreign Application Priority Data
Oct. 1, 2015 (KR) 10-2015-0138709

(51) Int. Cl. H01L 51/52

(52) U.S. Cl. CPC H01L 51/524; H01L 51/5284

(57) ABSTRACT

A window member may include: a base substrate having a display area, a first non-display area surrounding the display area, and a second non-display area surrounding the first non-display area; a first light blocking layer on the base substrate corresponding to the first non-display area; a first printed layer on the base substrate corresponding to the second non-display area; a second printed layer on the first light blocking layer and the first printed layer to overlap the first printed layer and a portion of the first light blocking layer; and a second light blocking layer on the second printed layer to overlap the first printed layer and a portion of the first light blocking layer. A display apparatus may include a display panel configured to display images and the window member configured to cover the display panel.

### CROSS-REFERENCE TO RELATED APPLICATION

This U.S. non-provisional patent application claims priority under 35 U.S.C. §119 to Korean Patent Application No. 10-2015-0138709, filed on Oct. 1, 2015 in the Korean Intellectual Property Office, the entire content of which is herein incorporated by reference. CL BACKGROUND

1. Field

Aspects of embodiments of the present invention are directed to a window substrate and a display apparatus including the window substrate.

2. Description of the Related Art

Electronic apparatuses such as mobile terminals, digital cameras, laptop computers, monitors, and televisions may include display apparatuses for displaying images. A display apparatus may include a display panel for generating and displaying images, and a window panel disposed over the display panel to protect the display panel. Various display apparatuses have been developed with a display panel, such as liquid crystal displays (LCD), organic light emitting displays (OLED), electro wetting display devices (EWD), plasma display panels (PDP), and electrophoretic display devices (EPD). The display panel may include a touch function. The window panel may be attached over the display panel. Images generated from the display panel may be provided to a viewer by passing through the window panel. The window panel may be designed in various colors.

### SUMMARY

Embodiments of the present invention provide for a window substrate and a display apparatus including the window substrate that are easy to manufacture and for which an error rate in recognizing the border between a display area and a non-display area is improved.

According to an embodiment of the present invention, a window member is provided. The window member includes: a base substrate having a display area, a first non-display area surrounding the display area, and a second non-display area surrounding the first non-display area; a first light blocking layer on the base substrate corresponding to the first non-display area; a first printed layer on the base substrate corresponding to the second non-display area; a second printed layer on the first light blocking layer and the first printed layer to overlap the first printed layer and a portion of the first light blocking layer; and a second light blocking layer on the second printed layer to overlap the first printed layer and a portion of the first light blocking layer.

The second printed layer may include a plurality of auxiliary printed layers laminated together.

Each of the first and second printed layers may have a white color.

Each of the first and second light blocking layers may have a black color.

The window member may further include a third light blocking layer on an inside surface of the second printed layer.

The third light blocking layer may connect the first light blocking layer to the second light blocking layer.

The first light blocking layer and the first printed layer may be on the same surface of the base substrate.

Each of the first printed layer and the first light blocking layer may include a multi-layered structure in which a plurality of layers is laminated.

The second light blocking layer may include a multi-layered structure in which a plurality of layers is laminated.

The first printed layer may include a plurality of first deco layers having different colors from one another, the first deco layers being horizontally arranged on one surface of the base substrate.

The second printed layer may include a plurality of second deco layers having different colors from one another, the second deco layers being horizontally arranged on one surface of the first printed layer.

The second deco layers may overlap and respectively correspond to the first deco layers.

The first light blocking layer may have a width between about 0.2 mm and about 0.4 mm.

In another embodiment of the present invention, a display apparatus is provided. The display apparatus includes a display panel configured to display images, and a window member configured to cover the display panel. The window member includes: a base substrate having a display area, a first non-display area surrounding the display area, and a second non-display area surrounding the first non-display area; a first light blocking layer on the base substrate corresponding to the first non-display area; a first printed layer on the base substrate corresponding to the second non-display area; a second printed layer on the first light blocking layer and the first printed layer to overlap the first printed layer and a portion of the first light blocking layer; and a second light blocking layer on the second printed layer to overlap the first printed layer and a portion of the first light blocking layer.

The second printed layer may include a plurality of auxiliary printed layers laminated together.

Each of the first and second printed layers may have a white color.

Each of the first and second light blocking layers may have a black color.

The first light blocking layer and the first printed layer may be on the same surface of the base substrate.

Each of the first printed layer and the first light blocking layer may include a multi-layered structure in which a plurality of layers is laminated.

The second light blocking layer may include a multi-layered structure in which a plurality of layers is laminated.

### BRIEF DESCRIPTION OF THE DRAWINGS

The accompanying drawings are included to provide further understanding of the present invention, and are incorporated in and constitute a part of this specification. The drawings illustrate example embodiments of the present invention and, together with the description, serve to better explain aspects and principles of the present invention. In the drawings:

FIG. 1 is a perspective view illustrating an example display apparatus according to an embodiment of the present invention;

FIG. 2 is an example cross-sectional view taken along line I-I′ of FIG. 1 according to an embodiment of the present invention;

FIG. 3 is a cross-sectional view illustrating an example display apparatus according to another embodiment of the present invention;

FIG. 4 is a cross-sectional view illustrating an example display apparatus according to another embodiment of the present invention;

FIG. 5 is a cross-sectional view illustrating an example display apparatus according to another embodiment of the present invention;

FIG. 6 is a cross-sectional view illustrating an example display apparatus according to another embodiment of the present invention; and

FIGS. 7A to 7E are cross-sectional views illustrating an example method of manufacturing a window member according to an embodiment of the present invention.

### DETAILED DESCRIPTION

Aspects and features of the present invention, and implementation methods thereof will be described through example embodiments described herein with reference to the accompanying drawings. The present invention may, however, be embodied in different forms and should not be construed as limited to the embodiments set forth herein. Rather, these embodiments are provided to more fully convey the scope of the present invention to those skilled in the art, as set forth in the claims and their equivalents. Like or similar reference numerals refer to like or similar elements throughout.

It will be understood that when an element or a layer is referred to as being “above” or “on” another element or layer, it may be directly above or on the other element or layer, or intervening layers or elements may also be present. On the contrary, when an element is referred to as being “directly on” another element or layer, it will be understood that no intervening layers or elements are present. The term “and/or” includes any and all combinations of one or more of the associated listed items.

The terms “below”, “beneath”, “lower”, “above”, and “upper” representing spatial relativity may be used to easily describe the correlation between one element or component and another element or component as shown in the drawings. The terms representing spatial relativity should be understood as terms including different directions of an element in use or in operation in addition to the direction shown in the drawings.

It will be understood that, although the terms first, second, etc., may be used herein to describe various elements, components, and/or sections, these elements, components, and/or sections should not be limited by these terms. These terms are mainly used to distinguish one element, component, and/or section from another element, component, and/or section. Thus, for example, a first element, a first component, or a first section discussed below may instead be termed a second element, a second component, or a second section without departing from the teachings of the present invention.

Embodiments described in the present specification may be described with reference to plan views and cross-sectional views that may be idealized, schematic diagrams of embodiments of the present invention. Accordingly, shapes of the exemplary views may be modified according to, for example, manufacturing techniques and/or allowable errors as would be apparent to one of ordinary skill. Therefore, embodiments of the present invention are not limited to the specific shapes illustrated in the example views, but may include other shapes that may be created according to routine or described manufacturing processes as would be apparent to one of ordinary skill. Areas shown in the drawings have general properties, and may be used to illustrate a specific shape of a semiconductor package region. Thus, this should not be construed as limiting the scope of the present invention.

Herein, the use of the term “may,” when describing embodiments of the present invention, refers to “one or more embodiments of the present invention.” In addition, the use of alternative language, such as “or,” when describing embodiments of the present invention, refers to “one or more embodiments of the present invention” for each corresponding item listed. Hereinafter, example embodiments of the present invention will be described in detail with reference to the accompanying drawings.

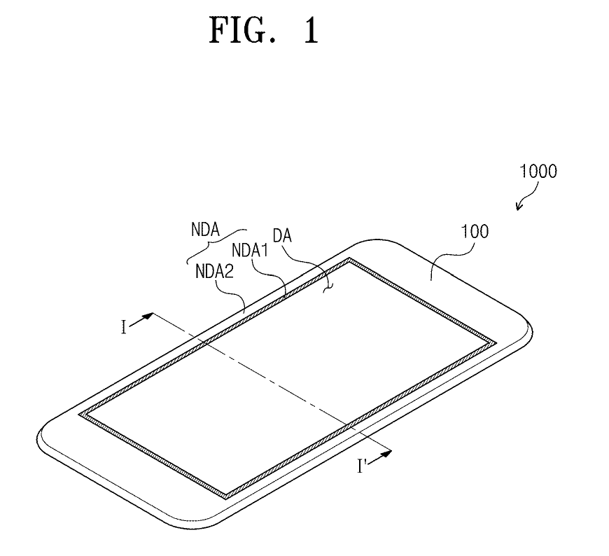

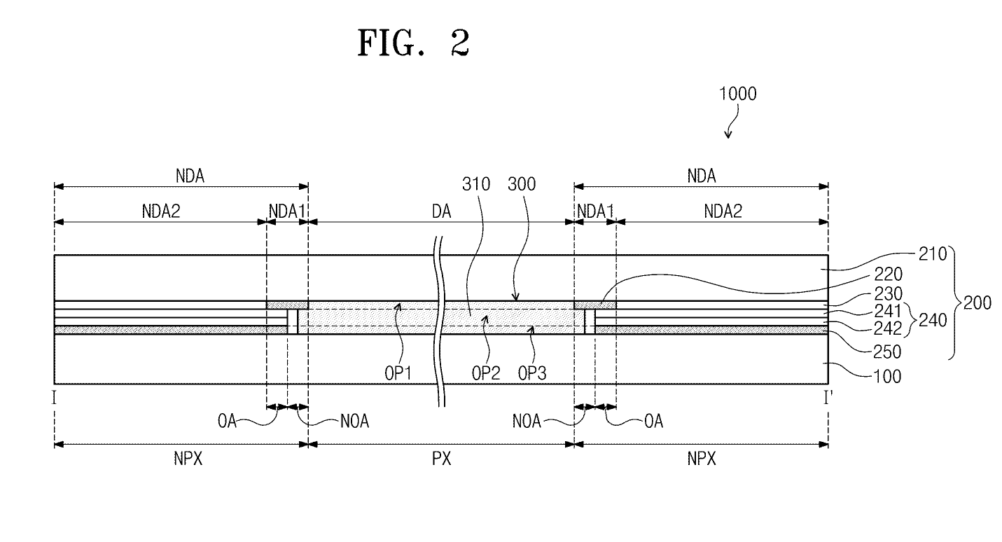

FIG. 1 is a perspective view illustrating an example display apparatus 1000 according to an embodiment of the present invention. FIG. 2 is an example cross-sectional view taken along line I-I′ of FIG. 1 according to an embodiment of the present invention. FIG. 1 illustrates the display apparatus 1000 as applied to a mobile phone. However, in other embodiments, display apparatus 1000 may be applied to various information providing apparatuses, such as televisions, computers, monitors, game machines, etc., to display images.

Referring to FIGS. 1 and 2, the display apparatus 1000 includes a display panel 100 and a window panel (or window substrate or window member) 200. In other embodiments, the display apparatus 1000 may further include a housing accommodating the display panel 100.

The display panel 100 may be configured to display images. The display panel 100 may be an organic light emitting display panel. However, the present invention is not limited to the kind of display panel 100. For example, in other embodiments, the display panel 100 may be a liquid crystal panel, a plasma display panel, an electrophoretic display panel, an electrowetting display panel, or the like.

The display panel 100 may include a pixel area PX and a non-pixel area NPX (for example, in a plan view). The display panel 100 may display images through the pixel area PX. By contrast, the non-pixel area NPX refers to the area of the display panel 100 on which images are not displayed. The non-pixel area NPX may surround the pixel area PX. The display panel 100 may include a plurality of pixels in the pixel area PX. In addition, the display panel 100 may include a drive unit (such as in the non-pixel area NPX) for driving the pixels. For example, the pixels may be driven by the drive unit to generate set or predetermined images.

The window member 200 may be disposed on the display panel 100 to cover the display panel 100. The window member 200 may be coupled to the display panel 100 through a coupling member. The window member 200 may include a base substrate 210, a first light blocking layer 220, a first printed layer 230, a second printed layer 240, and a second light blocking layer 250.

The base substrate 210 may have a transparent property to transmit light. A display area DA and a non-display area NDA may be defined on the base substrate 210. The display area DA may overlap or correspond to the pixel area PX of the display panel 100, and the non-display area NDA may overlap or correspond to the non-pixel area NPX of the display panel 100. Accordingly, light outputted from the display panel 100 may pass through the display area DA so that images may be displayed on the display area DA of the base substrate 210.

The non-display area NDA may be disposed adjacent to edge regions of the display area DA. The first light blocking layer 220, the first printed layer 230, the second printed layer 240, and the second light blocking layer 250 may be provided on the non-display area NDA. Accordingly, unlike the display area DA, the light outputted from the display panel 100 may be blocked by the layers 220, 230, 240, and 250, so that images (such as stray light or images) may not be displayed in the non-display area NDA of the base substrate 210. As an example, in one embodiment, the thickness of each of the layers 220, 230, 240, and 250 may be between about 2 μm and about 7 μm.

The non-display area NDA may include a first non-display area NDA1 and a second non-display area NDA2. The first non-display area NDA1 may be defined as that portion of the non-display area NDA that is adjacent to the display area DA, and may surround the display area DA. By contrast, the second non-display area NDA2 may be defined as that portion of the non-display area NDA that is not adjacent to the display area DA, but that is adjacent to the first non-display area NDA1 and may surround the first non-display area NDA1.

The first light blocking layer 220 may be disposed on the base substrate 210 corresponding to the first non-display area NDA1. A first opening part OP1 may be provided adjacent to and on an interior of the first light blocking layer 220 (for example, the first light blocking layer 220 may surround the first opening part OP1). The first opening part OP1 may correspond to the display area DA of the base substrate 210, and may be, for example, empty space or made of a transparent material. The first light blocking layer 220 may have a black color.

The first printed layer 230 may be disposed on the base substrate 210 corresponding to the second non-display area NDA2. For example, the first light blocking layer 220 and the first printed layer 230 may be disposed on the same surface of the base substrate 210. The first printed layer 230 may be connected to the first light blocking layer 220. The first printed layer 230 may have a white color.

The present invention is not limited to the kinds of colors of the first light blocking layer 220 and the first printed layer 230. For example, according to other embodiments, each of the first light blocking layer 220 and the first printed layer 230 may have various colors, such as blue and green.

The second printed layer 240 may be disposed on the first printed layer 230 corresponding to the second non-display area NDA2 and a portion of the first non-display area NDA1. For example, the second printed layer 240 may overlap the first printed layer 230. The second printed layer 240 may have a white color. In addition, an interior portion (e.g., closer to the display area DA) of the second printed layer 240 may extend into the first non-display area NDA1. Accordingly, the interior portion of the second printed layer 240 may overlap at least one portion of the first non-display area NDA1.

Accordingly, the portion of the first non-display area NDA1 overlapping the second printed layer 240 is defined to be the overlap area OA. In addition, the portion of the first non-display area NDA1 not overlapping the second printed layer 240 is defined to be the non-overlap area NOA. Accordingly, the second printed layer 240 may be disposed on the first light blocking layer 220 corresponding to the overlap area OA of the first non-display area NDA1 and the first printed layer 230 corresponding to the second non-display area NDA2.

The second printed layer 240 may include a plurality of auxiliary printed layers, such as first auxiliary printed layer 241 and second auxiliary printed layer 242. The color of the second printed layer 240 may be the same as that of the first printed layer 230. However, according to another embodiment, the color of the second printed layer 240 may be different from that of the first printed layer 230.

A second opening part OP2 may be provided adjacent to or on an interior of the second printed layer 240. For example, the second printed layer 240 may surround the second opening part OP2, possibly with a gap (such as an air gap) therebetween. The second opening part OP2 may overlap or correspond to the display area DA and all or part of the non-overlap area NOA of the first non-display area NDA1. The width of the second opening part OP2 may be greater than or equal to that of the first opening part OP1. The second opening part OP2 may be, for example, empty space or made of a transparent material.

The second light blocking layer 250 may be disposed on the second printed layer 240 corresponding to the second non-display area NDA2 and a portion of the first non-display area NDA1, such as the overlap area OA. As such, the second light blocking layer 250 may overlap the second printed layer 240. In other embodiments, the second light blocking layer 250 may overlap a smaller portion of the first non-display area NDA1 than that of the second printed layer 240

The color of the second light blocking layer 250 may be the same as that of the first light blocking layer 220. For example, the second light blocking layer 250 may have a black color.

An interior portion of the second light blocking layer 250 may extend into the first non-display area NDA1, such as the overlap area OA. Accordingly, an interior portion of the second light blocking layer 250 may overlap at least one portion of the first non-display area NDA1, such as the overlap area OA. For example, the interior portion of the second light blocking layer 250 may be disposed on the second printed layer 240 corresponding to the second non-display area NDA2 and overlap area OA of the first non-display area NDA1.

A third opening part OP3 may be provided adjacent to or on an interior of the second light blocking layer 250. For example, the second light blocking layer 250 may surround the third opening part OP3, possibly with a gap (such as an air gap) therebetween. The third opening part OP3 may overlap or correspond to the display area DA and all or part of the non-overlap area NOA of the first non-display area NDA1. The third opening part OP3 may be, for example, empty space or made of a transparent material.

As illustrated in FIG. 2, the area of the region where the interior portion of the second printed layer 240 overlaps the first non-display area NDA1 (namely the overlap area OA) may be equal to the area of the region where the interior portion of the second light blocking layer 250 overlaps the first non-display area NDA1 (again, the overlap area OA). In addition, the width of the third opening part OP3 may be equal to that of the second opening part OP2.

However, in another embodiment, the area of the region where the interior portion of the second printed layer 240 overlaps the first non-display area NDA1 may be different from the area of the region where the interior portion of the second light blocking layer 250 overlaps the first non-display area NDA1. For reasons such as this, in other embodiments, the width of the third opening part OP3 may be, for example, greater than that of the second opening part OP2.

In comparable window members, when the first light blocking layer 220 is not disposed on the base substrate 210, the border between the first printed layer 230 and the display area DA may not overlap the border between the second printed layer 240 and the display area DA. Accordingly, when a user views the base substrate 210, a border recognition error phenomenon in which the border between the non-display area NDA and the display area DA is unclearly viewed may occur.

However, according to embodiments of the present invention, the first light blocking layer 220 may be disposed on one surface of the base substrate 210, so that the border between the second printed layer 240 and the display area DA overlaps the first light blocking layer 220. For example, the second opening part OP2 may be surrounded by the second printed layer 240 and have a greater width than that of the first opening part OP1 as defined by the first light blocking layer 220. In this case, the border or area between the second opening part OP2 and the second printed layer 240 may overlap or coincide with the first light blocking layer 220 having a black color.

Thus, according to embodiments of the present invention, when a user views the base substrate 210, the border (such as a border formed by the second printed layer 240) is not viewed by the user because the border is covered by the first light blocking layer 220. Accordingly, an error phenomenon in recognizing the border between the non-display area NDA and the display area DA may be lessened or prevented.

In other embodiments, the widths of the first and second auxiliary printed layers 241 and 242 of the second printed layer 240 may be different from each other. As such, there may be a plurality of borders defined between the second opening part OP2 and the second printed layer 230.

In comparable window substrates, when the first light blocking layer 220 is not disposed on the base substrate 210, a light leakage phenomenon in which light provided from the display panel 100 leaks at interior portions of the first and second auxiliary printed layers 241 and 242 of the second printed layer 240 may occur.

However, according to embodiments of the present invention, interior portions of each of the first and second auxiliary printed layers 241 and 242 overlap or correspond to the first light blocking layer 220. As such, when a user views the base substrate 210, since a plurality of borders defined between the second opening part OP2 and the second printed layer 240 are covered by the first light blocking layer 220, the borders may not be viewed. Accordingly, even though the widths of the first and second auxiliary printed layers 241 and 242 of the second printed layer 240 may vary, a light leakage phenomenon may be lessened or prevented.

As an example, the first light blocking layer 220 may have a width between about 0.2 mm and about 0.4 mm. When the width of the first light blocking layer 220 is smaller than about 0.2 mm, high precision may be required for disposing the interior portion of the second printed layer 240 between the first light blocking layer 220 and the second light blocking layer 250, which may decrease the yield of the window member 200. Further, when the width of the first light blocking layer 220 is greater than about 0.4 mm, the width of the first light blocking layer 220 may be greater than that of a black matrix of the display panel 100 and thus, the area of the display area DA may be decreased.

A first space 300 may be defined in the regions of the first opening part OP1, the second opening part OP2, and the third opening part OP3, which are disposed between the display panel 100 and the base substrate 210. The first space 300 may be, for example, an air gap. However, according to another embodiment, the first space 300 may be partially or completely filled with a transparent polymer layer 310.

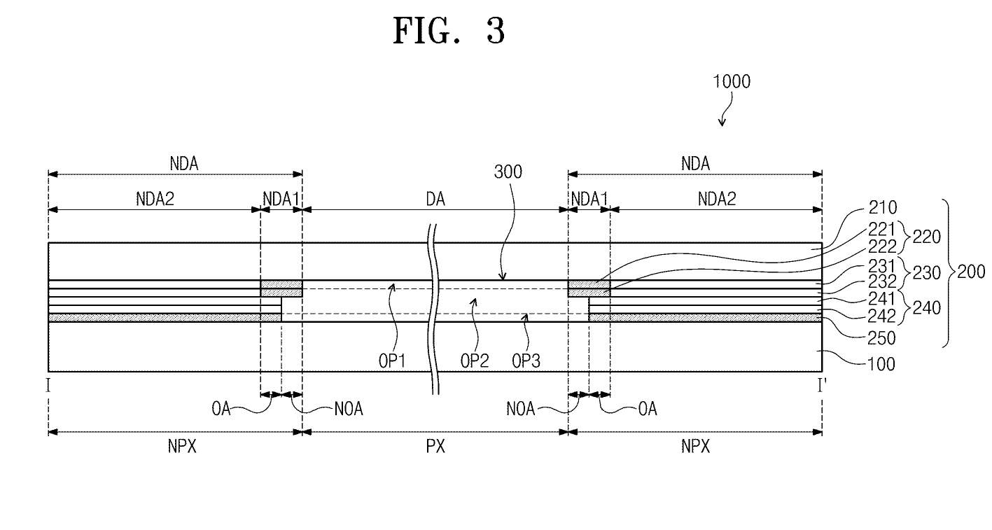

FIG. 3 is a cross-sectional view illustrating an example display apparatus 1000 according to another embodiment of the present invention. In describing FIG. 3, previously described components will be designated by the same reference numerals, and overlapping descriptions thereof may not be repeated.

Referring to FIG. 3, each of the first light blocking layer 220 and the first printed layer 230 may include a plurality of layers. For example, each of the first light blocking layer 220 and the first printed layer 230 may have a multi-layered structure in which a plurality of layers is disposed (e.g., laminated). For example, the first light blocking layer 220 may include a plurality of first sub light blocking layers 221 and 222, and the first printed layer 230 may include a plurality of first sub light printed layers 231 and 232. Accordingly, the thickness of the first light blocking layer 220 may be increased. Thus, the border between the non-display area NDA and the display area DA may be more clearly viewed.

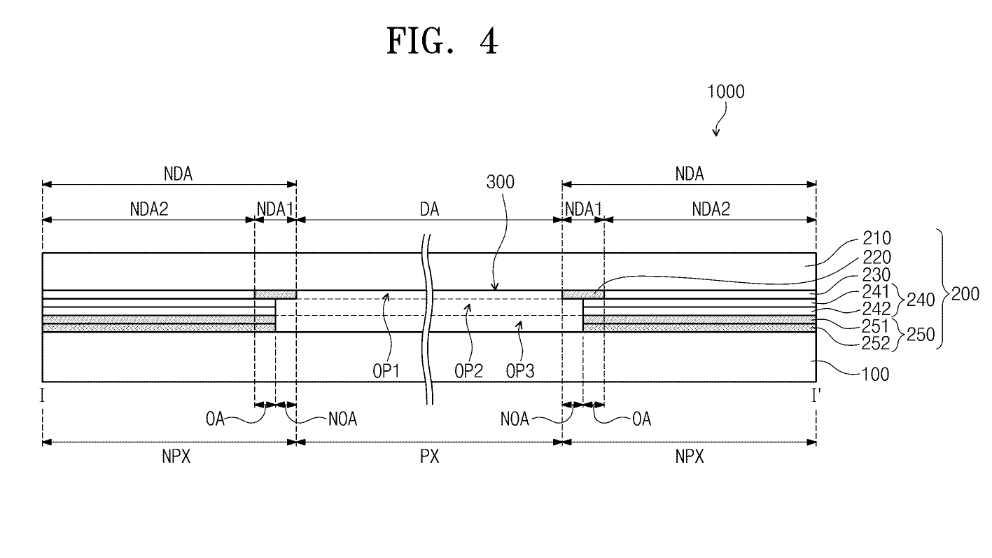

FIG. 4 is a cross-sectional view illustrating an example display apparatus 1000 according to another embodiment of the present invention. In describing FIG. 4, previously described components will be designated by the same reference numerals, and overlapping descriptions thereof may not be repeated.

Referring to FIG. 4, the second light blocking layer 250 may include a plurality of sub light blocking layers 251 and 252. For example, the second light blocking layer 250 may have a multi-layered structure in which a plurality of layers is disposed (e.g., laminated). Accordingly, the thickness of the second light blocking layer 250 may be increased. Thus, the border between the non-display area NDA and the display area DA may be more clearly viewed.

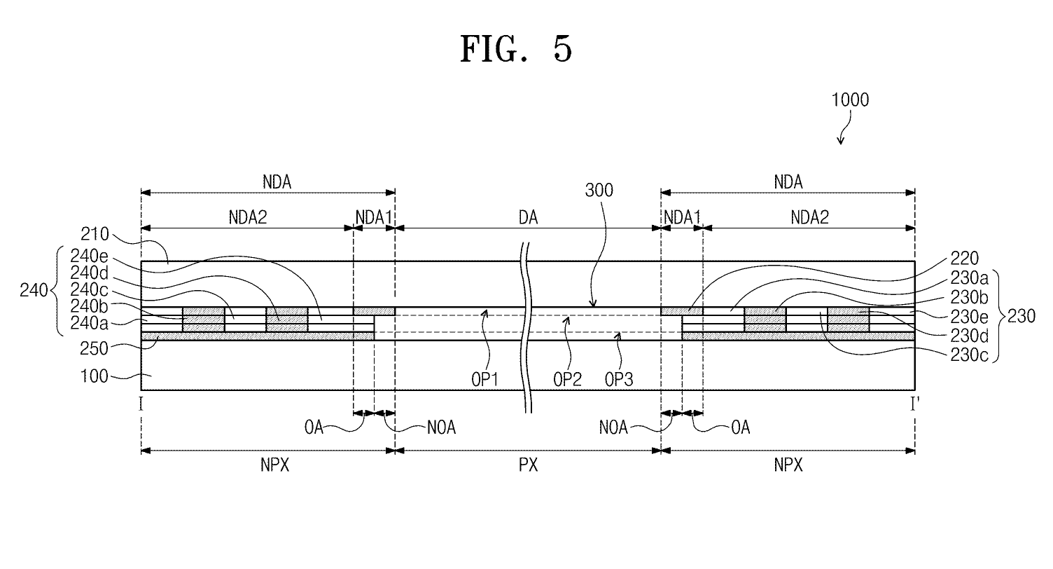

FIG. 5 is a cross-sectional view illustrating an example display apparatus 1000 according to another embodiment of the present invention. In describing FIG. 5, previously described components will be designated by the same reference numerals, and overlapping descriptions thereof may not be repeated.

Referring to FIG. 5, the first printed layer 230 may include a plurality of first deco (e.g., decoration or design) layers 230a to 230e. The first deco layers 230a to 230e may be horizontally arranged on one surface of the base substrate 210. The first deco layers 230a to 230e may have different colors from each other.

The second printed layer 240 may include a plurality (for example, a corresponding plurality) of second deco layers 240a to 240e. The second deco layers 240a to 240e may be horizontally arranged on one surface of the first printed layer 230. The second deco layers 240a to 240e may overlap the first deco layers 230a to 230e to respectively correspond (e.g., correspond one-to-one) to the first deco layers 230a to 230e.

The colors of the second deco layers 240a to 240e may be the same as those of the first deco layers 230a to 230e. As such, a clear pattern or shape may be viewed on the second non-display area NDA2. However, the present invention is not limited with respect to colors of the second deco layers 240a to 240e. For example, according to other embodiments of the present invention, the second deco layers 240a to 240e may have different colors from those of the first deco layers 230a to 230e.

According to embodiments such as FIG. 5, various patterns or shapes may be printed on the second non-display area NDA2. For example, the appearance of the display apparatus 1000 may be improved.

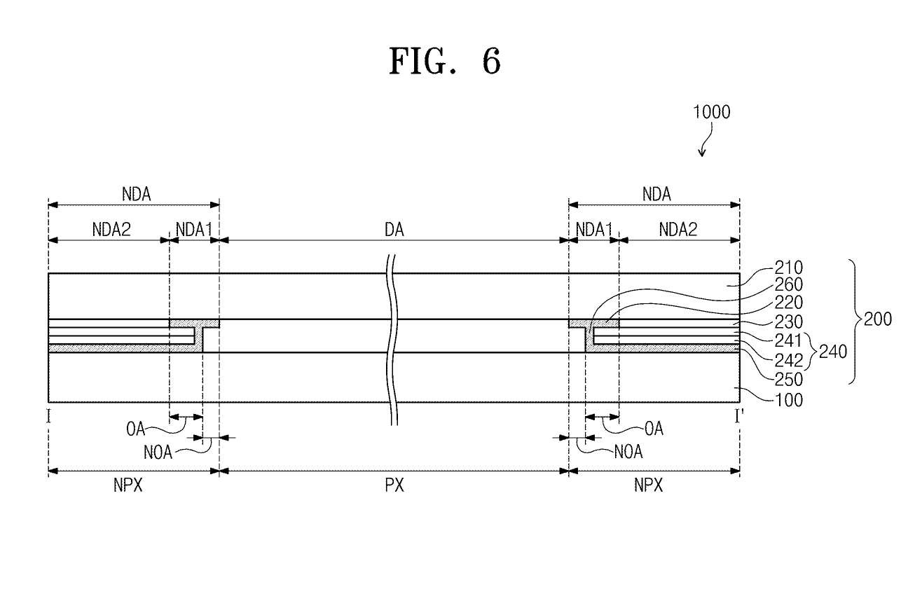

FIG. 6 is a cross-sectional view illustrating an example display apparatus 1000 according to another embodiment of the present invention. In describing FIG. 6, previously described components will be designated by the same reference numerals, and overlapping descriptions thereof may not be repeated.

Referring to FIG. 6, a window member 200 may further include a third light blocking layer 260 disposed on an inside surface (e.g., a side surface closer to the display area DA) of the second printed layer 240. The third light blocking layer 260 may be disposed between the first light blocking layer 220 and the second light blocking layer 250 and overlap one portion (such as the overlap area OA) of the first non-display area NDA1.

The third light blocking layer 260 may connect the first light blocking layer 220 to the second light blocking layer 250. The third light blocking layer 260 may have the same color as the first light blocking layer 220 and the second light blocking layer 250. For example, the third light blocking layer 260 may have a black color.

According to the embodiment of FIG. 6, the third light blocking layer 260 may block the light incident to an inside surface of the second printed layer 230 from a display panel 100. When light is incident to the inside of the second printed layer 230, light leakage may occur in the second non-display area NDA2. The third light blocking layer 260 may be disposed on the inside surface of the second printed layer 230 to block the light incident between the first light blocking layer 220 and the second light blocking layer 250. Thus, the window member 200 according to this embodiment may more efficiently lessen or prevent the light leakage phenomenon.

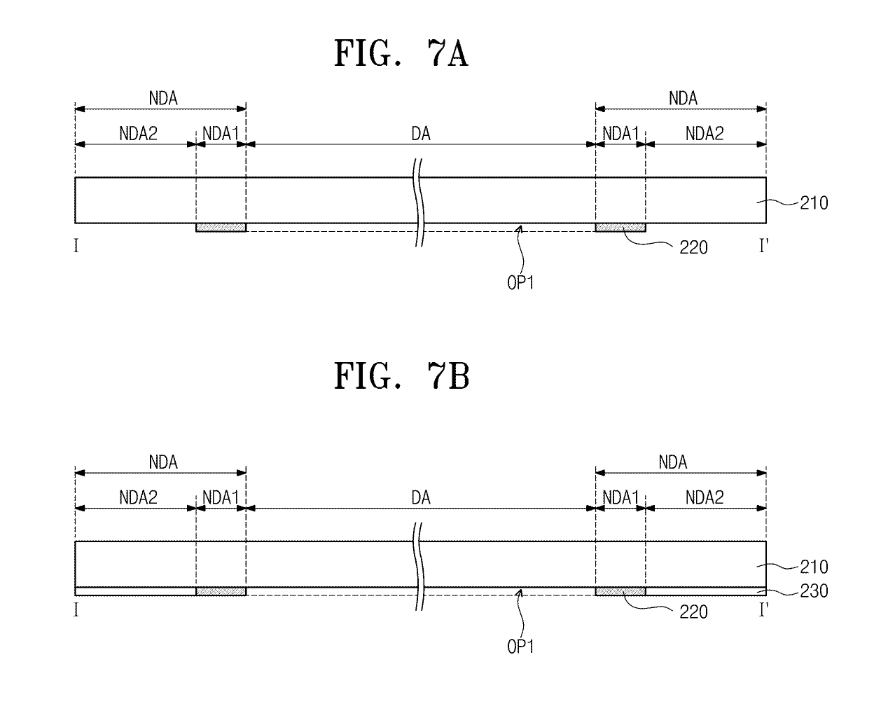

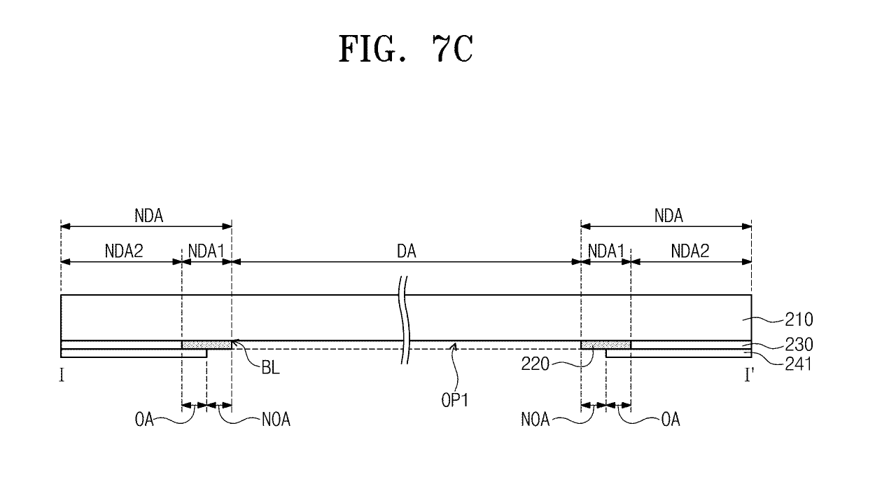

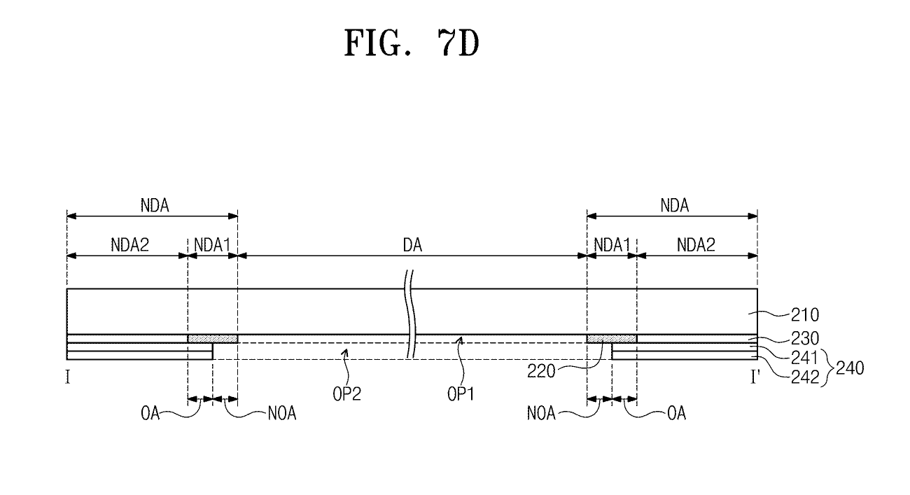

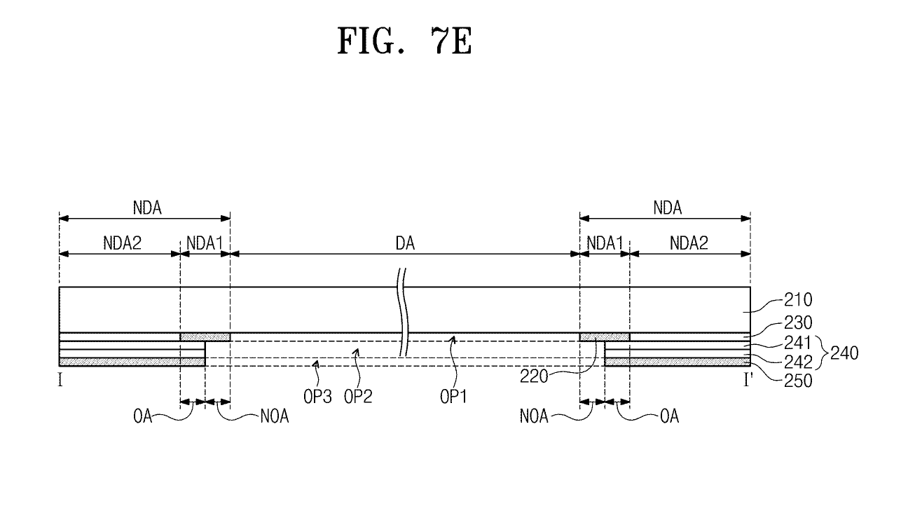

FIGS. 7A to 7E are cross-sectional views illustrating an example method of manufacturing a window member according to an embodiment of the present invention. In describing FIGS. 7A to 7E, previously described components will be designated by the same reference numerals, and overlapping descriptions thereof may not be repeated.

Referring to FIG. 7A, a first light blocking layer 220 may be printed on one surface of the base substrate 210. The first light blocking layer 220 may correspond to a first non-display area NDA1. A first opening part OP1 may be on an interior of (e.g., surrounded by) the first light blocking layer 220. The first opening part OP1 may overlap or correspond to (e.g., coincide with) a display area DA of the base substrate 210.

Referring to FIG. 7B, a first printed layer 230 may be printed adjacent to the first light blocking layer 220. The first printed layer 230 may correspond to the second non-display area NDA2. According to the embodiment of FIG. 7B, although the first light blocking layer 220 may be printed before the first printed layer 230, the present invention is not limited to the sequence of printing the first light blocking layer 220 and the first printed layer 230, and in other embodiments, the first printed layer 230 may be printed before the first light blocking layer 220.

Referring to FIG. 7C, a first auxiliary printed layer 241 may be printed on the first printed layer 230. One portion of the first auxiliary printed layer 241 may extend to the first non-display area NDA1 to overlap a set or predetermined region (e.g., the overlap area OA) of the first light blocking layer 220. For example, the first auxiliary printed layer 241 may be printed on the first printed layer 230 and the first light blocking layer 220.

Referring to FIG. 7D, a second auxiliary printed layer 242 may be printed on the first auxiliary printed layer 241. The interior portion of the second auxiliary printed layer 242 may extend to the first non-display area NDA1 to overlap a predetermined region (such as the overlap area OA) of the first light blocking layer 220.

A second opening part OP2 may be on an interior of (e.g., surrounded by) the second printed layer 240 including the first and second auxiliary printed layers 241 and 242. The second opening part OP2 may overlap or correspond to the display area DA and at least one portion (such as the non-overlap area NOA) of the first non-display area NDA1. The width of the second opening part OP2 may be greater than or equal to that of the first opening part OP1.

According to another embodiment, at least one auxiliary printed layer may be additionally printed on the second auxiliary printed layer 242. Thus, the thickness of the second printed layer 240 may be set by adjusting the number of auxiliary printed layers (such as using more than the first and second auxiliary printed layers 241 and 242).

Referring to FIG. 7E, a second light blocking layer 250 may be printed on the second auxiliary printed layer 242 of the second printed layer 240. The interior portion of the second light blocking layer 250 may extend to the first non-display area NDA1 to overlap a set or predetermined region (such as the overlap area OA) of the first light blocking layer 220. A third opening part OP3 may be on an interior of (e.g., surrounded by) the second light blocking layer 250.

According to some embodiments, the second opening part OP2 (surrounded by the second printed layer 240) may have a greater width than that of the first opening part OP1 (surrounded by the first light blocking layer 220). As such, the border between the second opening part OP2 and the second printed layer 240 may overlap or correspond to (e.g., coincide with) the first light blocking layer 220 having a black color.

In FIG. 7E, the border between the second opening part OP2 and the second printed layer 240 may be covered by the first light blocking layer 220 within a set or predetermined range. As such, the width of the second printed layer 240 may be freely set within a region (such as the overlap area OA) overlapping the first non-display area NDA1 in which the first light blocking layer 220 is disposed. Accordingly, the yield of the window member 200 may be improved.

According to the above and other embodiments of the present invention, a window member and a display apparatus including the window member may be easily manufactured, and an error rate in recognizing the border between a display area and a non-display area may be improved

While example embodiments are described above, a person skilled in the art may understand that many modifications and variations may be made without departing from the spirit and scope of the present invention defined in the following claims. In addition, embodiments disclosed in the present specification are not intended to limit the technical spirit of the present invention and the following claims and all technical spirits falling within equivalent scope are construed as being included in the scope of rights of the present invention.

What is claimed is:

1. A window member comprising:
a base substrate having a display area, a first non-display area surrounding the display area, and a second non-display area surrounding the first non-display area;
a first light blocking layer on the base substrate corresponding to the first non-display area;
a first printed layer on the base substrate corresponding to the second non-display area;
a second printed layer on the first light blocking layer and the first printed layer to overlap the first printed layer and a portion of the first light blocking layer; and
a second light blocking layer on the second printed layer to overlap the first printed layer and a portion of the first light blocking layer.

2. The window member of claim 1, wherein the second printed layer comprises a plurality of auxiliary printed layers laminated together.

3. The window member of claim 1, wherein each of the first and second printed layers has a white color.

4. The window member of claim 1, wherein each of the first and second light blocking layers has a black color.

5. The window member of claim 1, further comprising a third light blocking layer on an inside surface of the second printed layer.

6. The window member of claim 5, wherein the third light blocking layer connects the first light blocking layer to the second light blocking layer.

7. The window member of claim 1, wherein the first light blocking layer and the first printed layer are on the same surface of the base substrate.

8. The window member of claim 1, wherein each of the first printed layer and the first light blocking layer comprises a multi-layered structure in which a plurality of layers is laminated.

9. The window member of claim 1, wherein the second light blocking layer comprises a multi-layered structure in which a plurality of layers is laminated.

10. The window member of claim 1, wherein the first printed layer comprises a plurality of first deco layers having different colors from one another, the first deco layers being horizontally arranged on one surface of the base substrate.

11. The window member of claim 10, wherein the second printed layer comprises a plurality of second deco layers having different colors from one another, the second deco layers being horizontally arranged on one surface of the first printed layer.

12. The window member of claim 11, wherein the second deco layers overlap and respectively correspond to the first deco layers.

13. The window member of claim 1, wherein the first light blocking layer has a width between about 0.2 mm and about 0.4 mm.

14. A display apparatus comprising:
a display panel configured to display images; and
a window member configured to cover the display panel, the window member comprising:
a base substrate having a display area, a first non-display area surrounding the display area, and a second non-display area surrounding the first non-display area;
a first light blocking layer on the base substrate corresponding to the first non-display area;
a first printed layer on the base substrate corresponding to the second non-display area;
a second printed layer on the first light blocking layer and the first printed layer to overlap the first printed layer and a portion of the first light blocking layer; and
a second light blocking layer on the second printed layer to overlap the first printed layer and a portion of the first light blocking layer.

15. The display apparatus of claim 14, wherein the second printed layer comprises a plurality of auxiliary printed layers laminated together.

16. The display apparatus of claim 14, wherein each of the first and second printed layers has a white color.

17. The display apparatus of claim 14, wherein each of the first and second light blocking layers has a black color.

18. The display apparatus of claim 14, wherein the first light blocking layer and the first printed layer are on the same surface of the base substrate.

19. The display apparatus of claim 14, wherein each of the first printed layer and the first light blocking layer comprises a multi-layered structure in which a plurality of layers is laminated.

20. The display apparatus of claim 14, wherein the second light blocking layer comprises a multi-layered structure in which a plurality of layers is laminated.
